(19) United States
(12) Patent Application Publication
(10) Pub. No.: US 2024/0389225 A1
(43) Pub. Date: Nov. 21, 2024

(54) STRETCHABLE AND FLEXIBLE METAL FILM STRUCTURES

(71) Applicant: Liquid Wire Inc., Portland, OR (US)

(72) Inventors: Trevor Antonio Rivera, Portland, OR (US); Michael Adventure Hopkins, Portland, OR (US); Charles J. Kinzel, Portland, OR (US); Mark William Ronay, Portland, OR (US)

(21) Appl. No.: 18/683,738

(22) PCT Filed: Aug. 15, 2022
(86) PCT No.: PCT/US2022/074964

§ 371 Date: Feb. 14, 2024

Related U.S. Application Data
(60) Provisional application No. 63/233,689, filed on Aug. 16, 2021.
(60) Provisional application No. 63/261,266, filed on Sep. 16, 2021.

(51) Int. Cl. H05K 1/02; H05K 1/03; H05K 1/09; H05K 1/18; H05K 3/46

(52) U.S. Cl. CPC H05K 1/0283; H05K 1/0281; H05K 1/0346; H05K 1/09; H05K 1/181; H05K 3/465; H05K 2201/0154

(57) ABSTRACT

An apparatus comprises a metal layer 102, a fluid phase conductor 202 configured to overlap at least a portion of the metal layer, a stencil layer 204 having vias or channels containing the fluid phase conductor, and an encapsulation layer 206 configured to encapsulate the fluid phase conductor within the apparatus.

### PRIORITY APPLICATIONS

This application claims the benefit of priority to U.S. Provisional Patent Application Ser. No. 63/233,689, filed Aug. 16, 2021 and U.S. Provisional Patent Application Ser. No. 63/261,266, filed Sep. 16, 2021, the contents of both which are incorporated herein by reference in their entireties.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is an example of a flexible metal clad substrate in accordance with some embodiments.

FIG. 2A-2B illustrates cross-sectional and plan views, respectively, of a flexible metal clad substrate in accordance with some embodiments.

FIG. 3A-FIG. 3D illustrates cross-sectional and plan views of a flexible metal clad substrate including an electronic component, in accordance with some embodiments.

FIG. 4A-FIG. 4C illustrates a cross-sectional and plan views of a flexible metal clad substrate including an electronic component, in accordance with some embodiments.

FIG. 5 is a plan view of an example flexible circuit in accordance with some embodiments.

FIG. 6 is a top view of an example flexible circuit in accordance with some embodiments.

FIG. 7A-FIG. 7C are various view of an example flexible circuit of a chip package in accordance with some embodiments.

FIG. 8 is a view of an example flexible circuit board in accordance with some embodiments.

### DETAILED DESCRIPTION

Example methods and systems are directed to a stretchable and flexible metal film system, circuit, and method of producing said system and/or circuit. Examples merely typify possible variations. Unless explicitly stated otherwise, components and functions are optional and may be combined or subdivided, and operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

A stretchable and flexible metal film structure has been developed that may be adapted to a variety of systems with a variety of components to provide electrical connectivity between and among the various components. The stretchable and flexible metal film provides for the inclusion of conductive gel which provides further electrical connectivity between and among the various components with further improved flexibility and stretchability. The stretchable and flexible metal film structure also facilitates the inclusion of stencil-in-place structures, as disclosed herein. The various systems that may be formed with the use of the stretchable and flexible metal film structure may readily be incorporated into textile systems.

The stretch substrate layer is configured to stretch and flex and the areas with metal film or foil generally do not stretch and/or flex. When the metal is etched, the structure includes parts that stretch (e.g., via stretch substrate layer) and parts that do not (e.g., metal film/foil). This configuration allows the structure the flexibility and conformability that is desirable for various purposes (e.g., in wearable articles).

Additionally, the structure may include one or more electronic components embedded into, onto, or within one or more layers. In some embodiments, the electronic component is a surface mount technology (SMT) type or a surface mount device (SMD) type of component with connectors laying flush on a surface of a stretchable and flexible film structure. The electronic component in some embodiments, is a standard surface mount technology (SMT) of package type 0603 that has a length of 0.06 inches and a width of 0.03 inches utilizing a landing pad of ˜500 microns. The structure may also include components of larger sizes wherein the distance between the vias and/or contact pads (otherwise referred to as “webbing”) of said larger sized components are spaced apart at a distance between 100 to 250 microns. In some embodiments, the electronic component is a plastic very thin quad flat no-lead (PVQFN) 64 pin package type with a webbing between 50 to 100 microns. In some other embodiments, the electronic component is a small outline integrated circuit (SOIC) including an SOIC-8 package type.

Multiple other electronic components of varying sizes may also be embedded into the structure. The electronic component may be another type, for example, a through hole type component, optionally with connectors extending through the metal layer and/or penetrating into the vias (not shown), or some other component type or configuration. It is understood that the specified package type and size described herein is an example and other package types and sizes exist and may be used in accordance with the disclosure. The method of mounting such electronic components may also differ based on the type of component.

The embodiments and example implementation details described below are for purposes of illustration. The drawings are not necessarily shown to scale. The inventive principles are not limited to these embodiments and details.

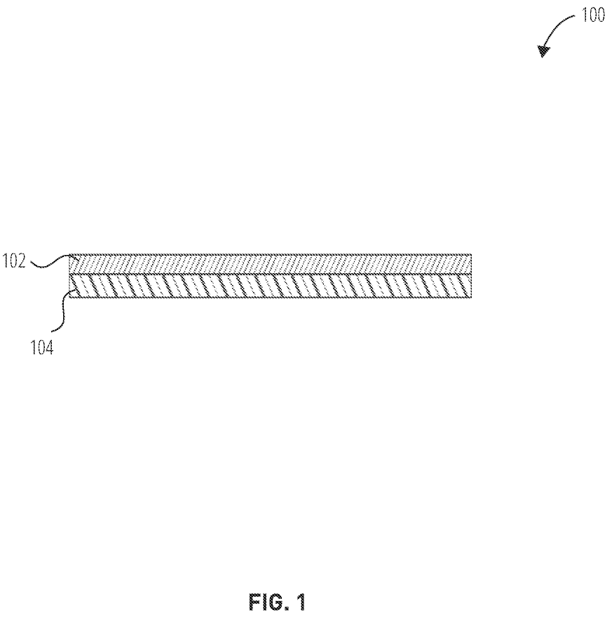

FIG. 1 is an example of a stretchable and flexible metal film structure 100 in accordance with some embodiments. The stretchable and flexible metal film structure 100 includes a metal layer 102 and stretch substrate layer 104. In some embodiments, the metal layer 102 forms a continuous metallic layer coupled to stretch substrate layer 104. In some embodiments, the metal layer 102 forms metallic traces coupled to stretch substrate layer 104 in the form of a metallic foil. The metallic traces are patterned to form electrical traces, vias, and pads for electric components. The metal layer 102 may be coupled or otherwise attached onto the stretch substrate layer 104 (e.g., deposited, adhered, or otherwise secured to the stretch substrate layer 104). The metal layer 102 may in some embodiments be composed of oxygen-free copper.

In some embodiments, the stretch substrate layer 104 may be formed of one of: a B-stage resin film, a C-stage resin film, an adhesive, thermoplastic polyurethane (TPU), and/or silicone, among other suitable compounds or materials.

Although two layers are illustrated in FIG. 1, it is understood that in this and the various examples herein incorporating the stretchable film structures or other structures formed according to the principles of the stretchable film structure, the number of layers may be increased as desired (e.g., according to an alternating pattern of stretchable substrate layers 104 separating metal layers (e.g., metal layer 102)).

The examples herein may incorporate multiple metal layers, multiple stretchable substrate layers, among various other additional layers that may be configured in different ways as desired.

The stretchable and flexible metal film structure 100 may utilize the metal layer 102 layer to electrically couple to or with external components of a larger system, such as a power source, external processor, control circuitry, and various discrete electrical and/or electronic components and the like.

In an example, the stretchable and flexible metal film structure 100 may be or may include a second metal on a second major surface of the substrate layer 104 opposite the major surface on which the metal layer 102 is positioned, as illustrated. Details of a substrate layer 104 are disclosed in U.S. Patent Application Publication No. 2020/0381349, “CONTINUOUS INTERCONNECTS BETWEEN HETEROGENEOUS MATERIALS”, Ronay et al., which is incorporated by reference herein in its entirety. In various examples, the stretchable and flexible metal film structure 100 may be or may include the structure disclosed in Patent Cooperation Treaty Application No. PCT/JP2017/045989, STRETCHABLE MEMBER WITH METAL FOIL, Tangyii et al., which is incorporated by reference herein in its entirety, or any suitable alternative.

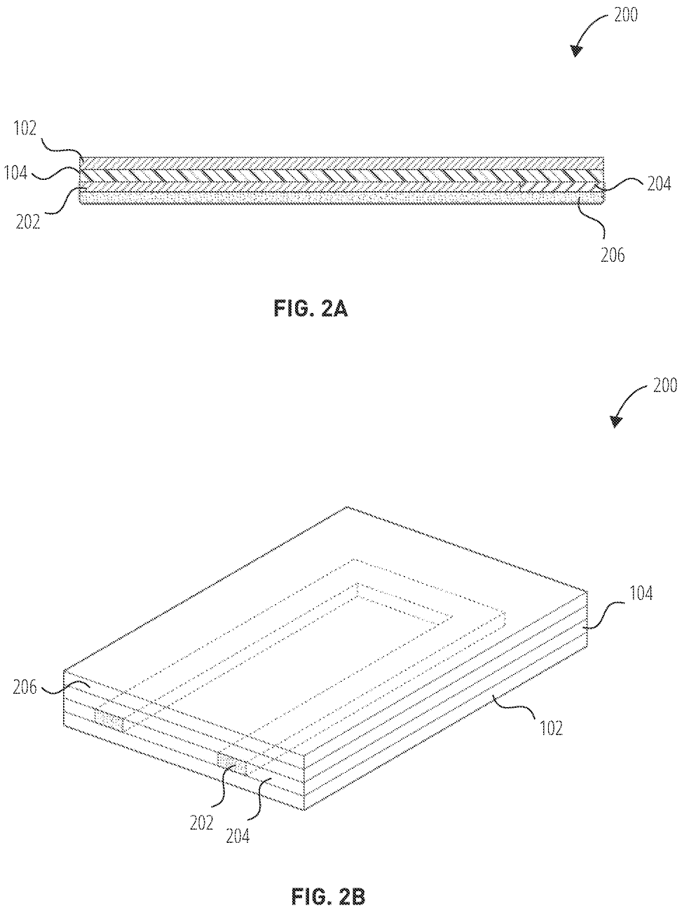

FIGS. 2A-2B are example views of a cross-section and a bottom perspective view of a stretchable and flexible metal film structure 200. The stretchable and flexible metal film structure 200 may in some embodiments be an extension of stretchable and flexible metal film structure 100 and include various additional components.

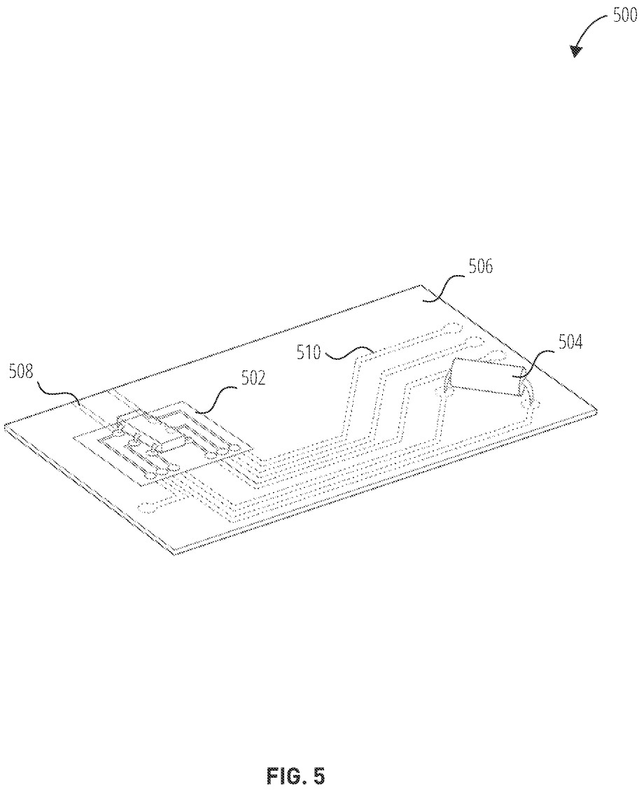

Stretchable and flexible metal film structure 200 includes, additional to the components shown in stretchable and flexible metal film structure 100, a stencil layer 204, a stencil layer 204, together which form stencil-in-place structure 506 (FIG. 5). Additionally, stretchable and flexible metal film structure 200 includes a metal gel 202.

Metal layer 102 may be a metal layer 102 as described with respect to FIG. 1. Stretch layer 104 may be comprised of a stretch substrate 104 as described with respect to FIG. 1.

Stencil layer 204 may be one of several stencil layers forming one or more vias or channels throughout the layer and containing conductive gel (e.g., metal gel 202). In some embodiments, the metal gel 202 fills the one or more vias and/or channels of the stencil layer 204.

Encapsulation layer 206 may be an encapsulant and/or an encapsulation layer configured to encapsulate a component and/or one or more layers of the stretchable and flexible metal film structure 200. In some embodiments, the stencil layer 204 is configured to encapsulate the metal layer 102 and isolate the metal layer 102 from other layers and/or environmental conditions. In some embodiments, the stencil layer 204 is made of TPU, B-stage resin or thermosetting film, a C-stage resin or thermosetting film, a thermosetting resin generally, an elastomer generally, or any other suitable encapsulant material.

In some embodiments, a combination of stencil layer 204, metal gel, and encapsulation layer 206 is referred to herein as a stencil-in-place structure (e.g., stencil-in-place structures 506, FIG. 5).

Metal gel 202 may be a conductive gel or other fluid phase conductor inserted on or within the layers of stretchable and flexible metal film structure 100 or 200 to provide electrical connectivity between and/or among various components within the structure and promotes improved flexibility and stretchability of the structure.

FIG. 2B is a bottom perspective view of stretchable and flexible metal film structure 200 in accordance with some embodiments. As shown, metal layer 102, stretch substrate 104, stencil layer 204 can be configured and adhered together in a sandwich of layers. In some embodiments, stencil layer 204 includes one or more channels filled with metal gel 202. In some embodiments, the metal layer 102 is configured to act as a ground plane for the stretchable and flexible metal film structure 200. In some embodiments, the metal layer 102 is coupled to a ground terminal of a circuit. As described with greater detail with respect to FIG. 5, stretchable and flexible metal film structure 200 may be a building block of a larger system.

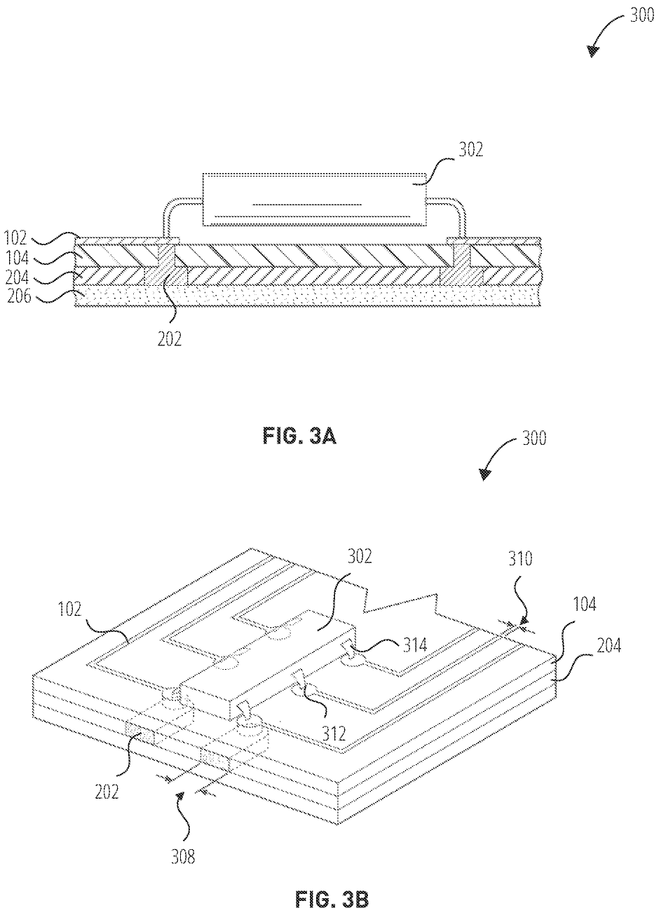

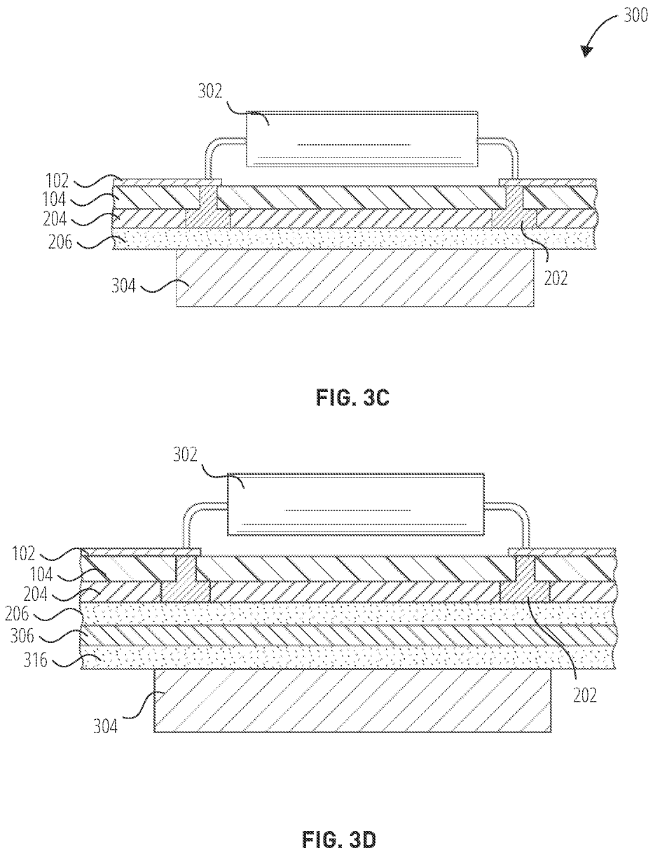

FIG. 3A-3D provide various views of a stretchable and flexible metal film structure 300 in accordance with some embodiments.

FIG. 3A is a cross-section view of a portion of a stretchable and flexible metal film structure 300 including an electronic component 302. As shown, an electronic component 302 is coupled to metal layer 102. The metal layer 102 is metallic and provides electrical coupling from the electronic component 302 through metal gel 202 of stencil layer 204. The electronic component 302 may be attached on and electrically coupled to the metal layer 102. In some embodiments, stencil layer 204 acts as an encapsulant for the metal gel 202. Optionally or additionally, the electronic component 302 may be attached to the structure 300 by adhesion to the substrate layer 104, e.g., using an adhesive and/or an adhesive characteristic of the substrate layer 104.

It is understood that although metal layer 102 is only labelled on the left side of the electronic component 302, there may be one or more instances of contact between the metal layer 102 and electronic component 302 (e.g., on the right side of electronic component 302). Correspondingly, vias and/or channels within stretch substrate layer 104 and stencil layer 204 filled with or otherwise containing metal gel 202 may be labelled in one location but exist in other locations (e.g., right side of electronic component 302). While stencil-in-place structures are shown for illustrative purposes, it is to be recognized and understood that the principles disclosed herein may be applied to any of a variety of alternative structures, including but not limited to any structures disclosed in Patent Cooperation Treaty application PCT/US2022/070853, “DEVICES, SYSTEMS, AND METHODS OF MAKING AND USING HIGHLY SUSTAINABLE CIRCUITS”, Kruskopf et al., filed Feb. 25, 2022, which is incorporated by reference herein in its entirety.

FIG. 3B is an isometric view of stretchable and flexible metal film structure 300 in accordance with some embodiments. As shown, electronic component 302 is adhered to a stretchable substrate 104. The electronic component 302 includes one or more connectors 314 of the electronic component 302. Each of the one or more connectors 314 is electrically coupled by way of one or more vias (e.g., via 312). In some embodiments, each corresponding connector of electronic component 302 is electrically coupled to the metallic traces of metal layer 102 of stretchable and flexible metal film structure 300 through via 312 that is filled with metal gel 202.

In some embodiments, a fluid trace width 308 is smaller than a metal trace width 310. The fluid trace width 308 may vary ranging from approximately 0.05 mm to 1 mm and may have trace lengths of approximately 10 cm in length. In some embodiments the fluid trace width 308 may have a width of not less than 0.05 mm to about 0.5 mm. In such examples, the trace may experience high temperatures that may create a discontinuity in the trace when carrying a current above about 1.5 Amperes. In the event of excess heat buildup in the metal gel 202, the metal gel 202 may self-heal after returning to a low current state (e.g., lower than 1 Ampere). It is also possible that high temperatures may damage the integrity of the structure 300, for example melting or burning a hole into one of the layers.

FIG. 3C is a first cross-section view of a first embodiment of a stretchable and flexible metal film structure 300 in accordance with some embodiments. Similar to the stretchable and flexible metal film structure 300 shown in FIG. 3A, the stretchable and flexible metal film structure 300 includes an electronic component 302, a metal layer 102, a stretch substrate 104, stencil layer 204, stencil layer 204, and one or more via 312 filled with metal gel 202.

Additionally, the stretchable and flexible metal film structure 300 of FIG. 3C includes a reinforcing member 304, such as a stiffener or a stretch lockout feature. In some embodiments, reinforcing member 304 is a textile segment, a polymer film segment, e.g., a polyimide film, or any other suitable flexible material. In some embodiments, the stiffener is configured underneath an electronic component 302 to support the electronic component 302. In some embodiments, the reinforcing member 304 is inserted between two layers of stretchable and flexible metal film structure 300 or is configured as a bottom layer of stretchable and flexible metal film structure 300 (as shown in FIG. 3C). In some embodiments, the reinforcing member 304 causes the stretchable and flexible metal film structure 300 to have a bend radius larger than twice the length of the electronic component 302. The bend radius may be determined, measured or calculated with the reinforcing member 304 incorporated to the structure 300 and prior to attachment of component 302. The bend radius may be calculated using the principles of IPC-2223's design standards.

The reinforcing member 304 may be used to support electronic component 302 on stretchable and flexible circuits. To avoid damaging the electronic component 302, bending, twisting, or stretching of the electronic component 302 may need to be avoided. In some embodiments, when a radius of curvature of the component (e.g., electronic component 302) on a stretchable and flexible circuit is exceeded, the component may break and/or connection points may decouple from the structure 300.

As described herein, a section of stiffener (e.g., reinforcing member 304 made of polyimide (PI) sheet or film) can be used to keep the circuit from reaching a maximum bend radius. In some embodiments, a stiffened layer of a glass-reinforced epoxy laminate material (FR4) is placed beneath one or more sections of PI board including components (e.g., electronic component 302) or may constitute the reinforcing member 304 on its own. In some embodiments, the reinforcing member extends past the edge of the components by up to 5 mm, or as little as ˜0.1 mm. In some examples, the reinforcing member 304 may have a smaller footprint than the electronic component 302. In one example, a footprint for a component layout is about 3 mm×3 mm, or 9 mm∧2, a reinforcing member, or stiffened segment of 4 mm×4 mm or 16 mm∧2 would be placed underneath the component. In some embodiments, the reinforcing member may be between 0.1 to 2 mm in thickness, depending on the stiffness of the structure 300 without the reinforcing member and the modulus of the material selected for reinforcement member 304.

FIG. 3D is a cross-sectional view of a second embodiment of a stretchable and flexible metal film structure 300, similar to the stretchable and flexible metal film structure 300 of FIG. 3C, in accordance with some embodiments. The structure 300 of this example is similar to the one shown in FIG. 3C with the addition of another stencil and isolation layer, 306 and 316, respectively. In some embodiments, additional stencil and/or isolation layers may be used. The additional layers enable multi-layer circuits to be patterned with fluid phase or metal gel conductors within each stencil layer. Depending on the pattern of the circuits in each layer, the isolation layers may be used to prevent electrical coupling of individual traces where this is undesirable. In some embodiments, a reinforcing member 304 may vary in thickness depending on the dimensions of the electronic component 302 and the desired bending stiffness profile of the structure below.

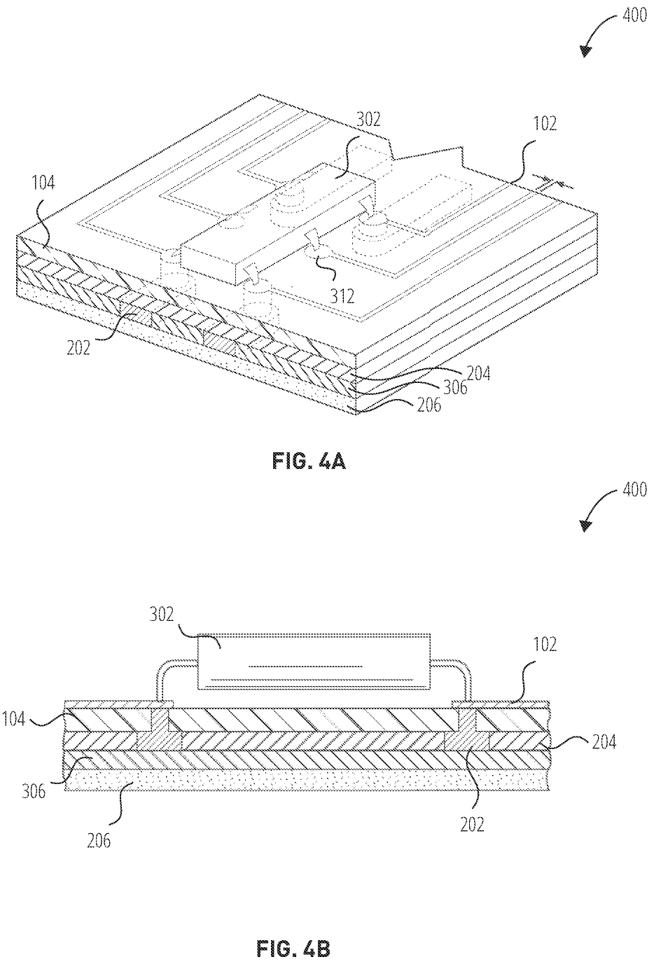

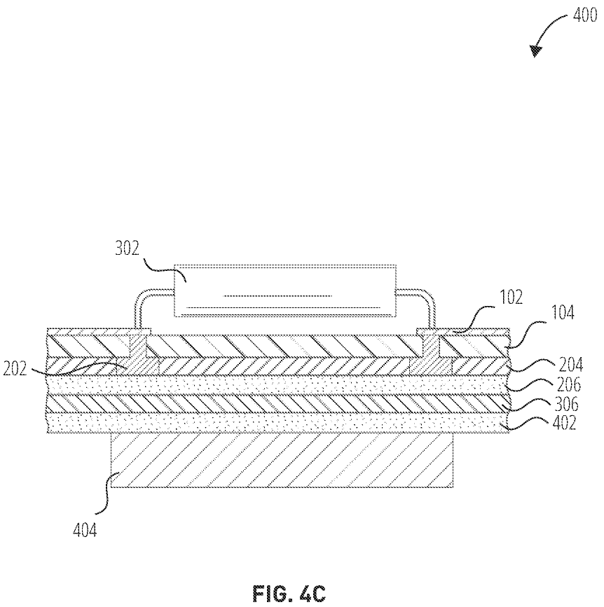

FIG. 4A-4C provide isometric and sectional views of a second embodiment of a portion of a stretchable and flexible metal film structure 300 in accordance with some embodiments.

FIG. 4A is a top isometric view of a stretchable and flexible metal film structure 400 in accordance with some embodiments. The stretchable and flexible metal film structure 400 includes an electronic component 302 coupled to a metallic trace of metal layer 102 coupled to stretch substrate 104. Further, the electronic component 302 is electrically coupled to metal layer 102 by way of via 312 including metal gel 202. Although the via 312 shown in FIG. 4A is depicted as having a uniform cylindrical shape as the vias overlap and traverse through the layers, it is understood and appreciated that the vias may differ in dimensions based on the layer in which the via resides. For example, a contact pad in a top layer (e.g., metal layer 102) may have a diameter of 1 mm, a via in a middle layer (e.g., stretch substrate layer 104) below the contact pad of the top layer may have a diameter of 0.75 mm, and a via in a bottom layer below the middle layer may have a diameter of 0.5 mm. In another example, the size of vias may differ in an alternating configuration based on the layer in which the via resides. A contact pad in a top layer (e.g., metal layer 102) may have a diameter of 1 mm, a via in a middle layer (e.g., stretch substrate layer 104) below the contact pad of the top layer may have a diameter of 0.75 mm, and a via in a bottom layer or a layer below the middle layer may have a diameter of 1 mm. The dimensions of the vias are understood to be configurable and variable as desired. In some embodiments, the stretchable and flexible metal film structure 400 includes a stencil layer 204, a second stencil layer 306, and encapsulation layer 206.

FIG. 4B is a cross sectional view of the stretchable and flexible metal film structure 400 FIG. 4A in accordance with some embodiments. The section is taken approximately at the center of contact pad of trace 310 substantially orthogonal to a length of the electronic component 302. In some embodiments, electronic component 302 is electrically coupled to a surface of a metal layer 102 that is in electrical contact with metal gel 202. In some embodiments, stretch substrate 104 is used to encapsulate the metal gel 202 in one or more channels of stencil layer 204. Additional layers may include a second stencil layer 306 and an encapsulation layer 206.

FIG. 4C is a cross sectional view of a second embodiment of the stretchable and flexible metal film structure 400 of FIG. 4A in accordance with some embodiments. Similar to the stretchable and flexible metal film structure 400 shown in in FIG. 4B and sectioned at the same location as the structure 300 of FIG. 4B, an electronic component 302 is coupled to the metal layer 102. In some embodiments, the stretchable and flexible metal film structure 400 includes an additional isolation layer 206 configured to isolate the pattern of apertures, slots or channels within the stencil layer 204 and/or extend a depth vias/channels provided within the layer containing metal gel 202, so as to enable electrical coupling to the various other layers. Encapsulation layer 402 is configured to encapsulate the metal gel 202 in the additional second stencil layer 306. An additional or optional reinforcing member 404 may be coupled to the stretchable and flexible metal film structure 400 similarly as described for the structure 300 of FIGS. 3C and 3D.

FIG. 5 is a top isometric view of an example flexible circuit in accordance with some embodiments. Flexible circuit 500 includes a board 506 that may include one or more stencil-in-place structures. An island structure 502 as described herein may be similar to one of the stretchable metal clad film structures disclosed above, e.g., structures 200, 300, 400 may be coupled to flexible circuit 500. An additional electronic component 504 may be included in flexible circuit 500, physically attached to a stencil-in-place portion of the board 506 and configured to electrically couple to metal gel traces 508 and 510, and/or island structure 502 as shown, or in various configurations in accordance with circuit design conventions. In some embodiments, the thicknesses of metal gel traces 508 and 510 may differ from metal traces provided on the island structure 502. As described herein, island structure 502 includes at least a stretch substrate 104, a metal layer 102 provided with a pattern of metal traces and contact pads, and an electronic component 302 and may be a separate circuit configured to be placed onto or within a larger circuit (e.g., flexible circuit 500). The island structure 502 may be electrically coupled to traces of the stencil-in-place portion of flexible circuit 500 by one or more vias in one or more layers of both the island structure 502 and flexible circuit 500. Such vias may extend to the contact pads of the island structure 502 and may be filled with metal gel alone and/or in combination with another fluid phase conductor, a conductive epoxy, solder or other conductive medium physically and/or electrically coupled to the contact pads.

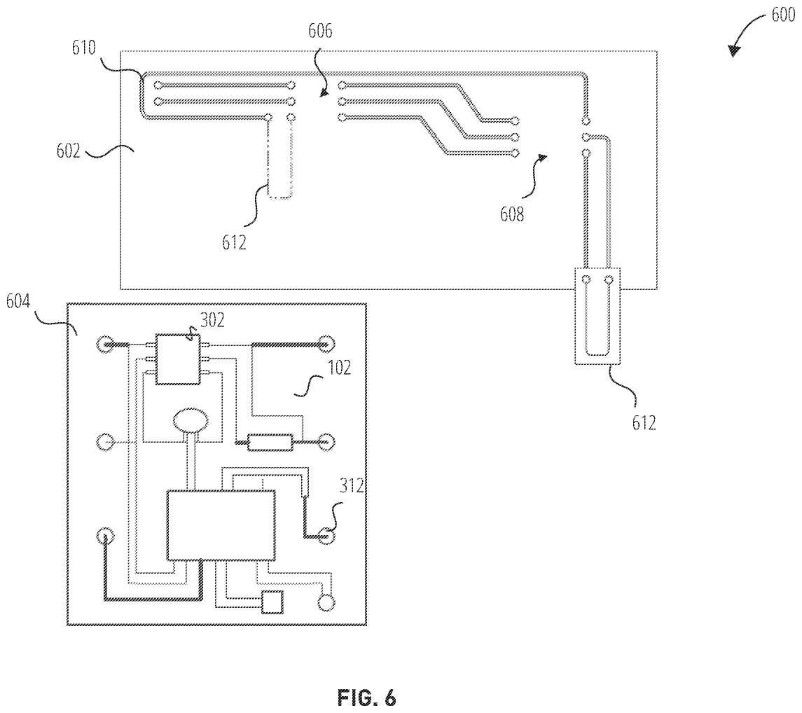

FIG. 6 is a top view of an example flexible circuit in accordance with some embodiments. Flexible circuit system 600 includes a flexible circuit 602 and island structure 604. Similar to the flexible circuit 500, flexible circuit system 600 shows discrete flexible circuit 602 and discrete island structure 604. Flexible circuit 602 may be a stencil-in-place structure as disclosed above. Locations 606 and 608 identify physical regions within flexible circuit 602 configured to receive island structure 604. In some embodiments, flexible circuit 602 includes one or more traces 610 that are filled with a fluid phase conductor such as a metal gel as disclosed above. One or more optional sensors or external devices 612 may be provided on the flexible circuit 602, and, as shown in this example, may be attached to the flexible circuit or integrated into the stencil-in-place structure.

The island structure 604, shown here as enlarged in comparison to the flexible structure to show greater detail, may be substantially as disclosed above. In some embodiments, island structure 604 includes an electronic component 302, one or more metallic traces in a metal layer 102, and at least one or more via 312. The island structure 604 may have at least one stretchable substrate layer, and the vias may be provided in the substrate layer. Traces of the island structure may be formed from a metal layer, such as a foil, and contact pads may be provided for electrically coupling to the flexible circuit 602. One or more contact pads may be positioned directly over one or more vias. It may be appreciated that the density of components on the island structure may be significantly greater than that of the flexible circuit 602.

The density of components as contemplated in this disclosure may be characterized as the number of components electrically and/or physically coupled to a structure per unit size of the structure. For example, a structure having 10 components attached thereto and a size of 2cm by 2.5 cm would have a density of two components per cm∧2. Component density may be useful in characterizing the resolution to which a structure may be manufactured, and thereby inform whether it may be made entirely from a stencil in place process utilizing a fluid phase conductor as traces, or whether at least a portion of the structure may be manufactured utilizing a metal layer in combination with a flexible and/or stretchable substrate and at least some of the traces formed from the metal layer.

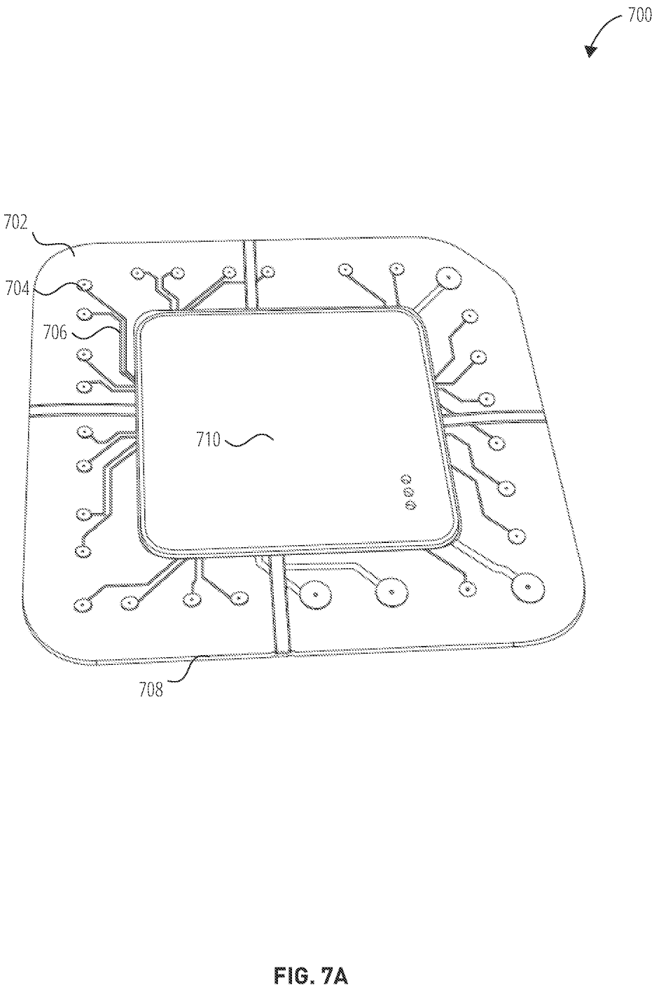

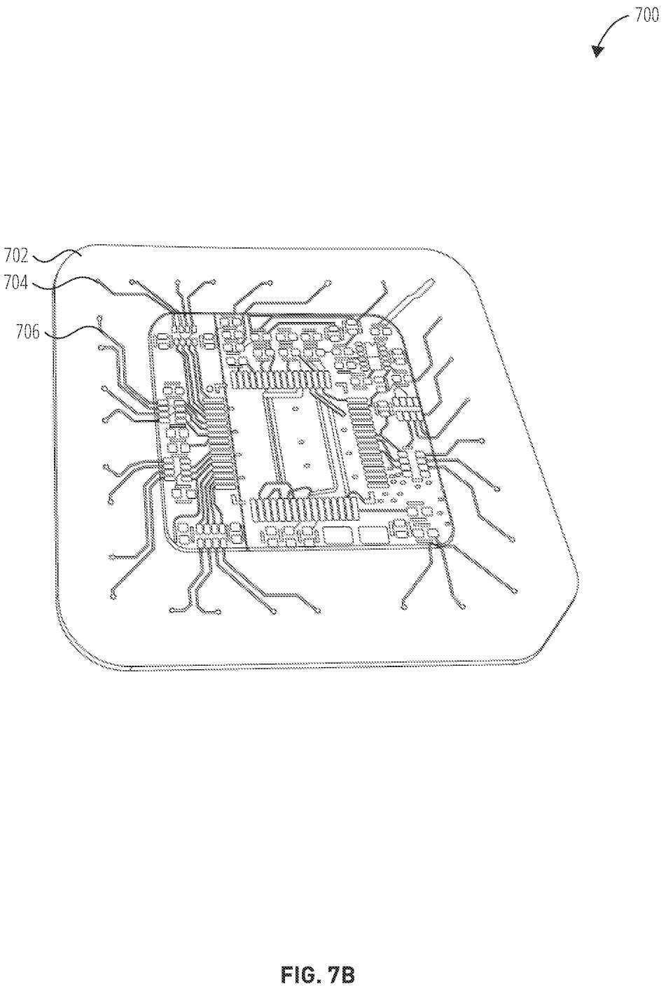

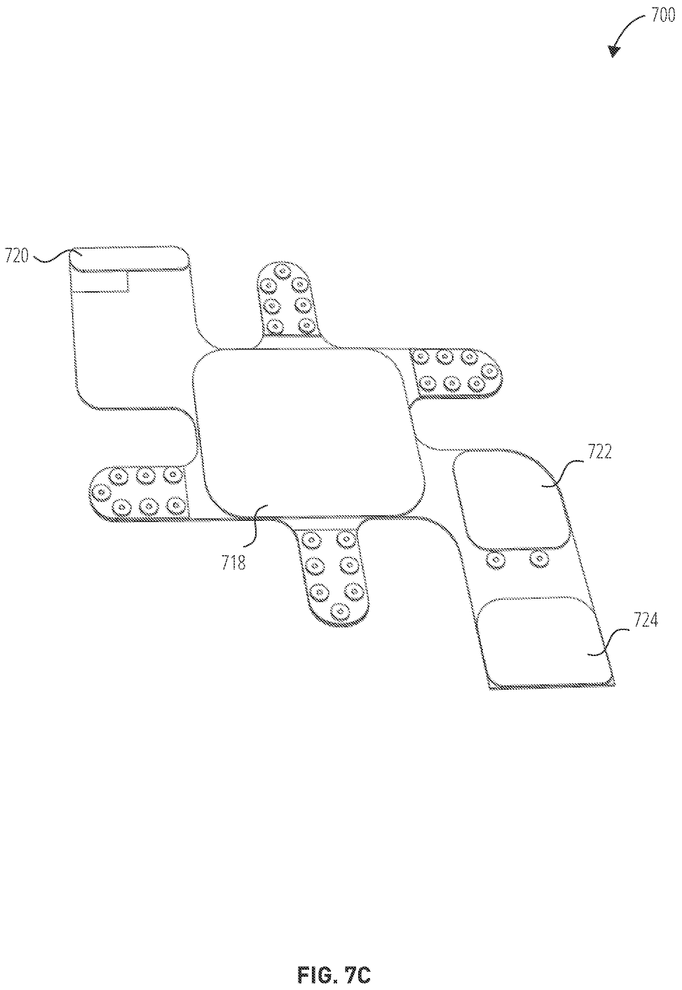

FIG. 7A-FIG. 7C are various view of an example flexible circuit of a chip package in accordance with some embodiments. In some embodiments, the example flexible circuit system 600 is configured to include a discrete island structure (e.g., 502, 604) to be implemented on a larger circuit.

FIG. 7A is a top view of package 700 including chip 710 (e.g., quad-flat no-lead (QFN) chip), one or more traces 706, and one or more vias 704. The package 700 may include a flexible substrate 702 or may be encapsulated by a flexible material as described with respect to encapsulation layer 206 and configured to encapsulate the chip 710. The package 700 may comprise one or more layers 708 that are assembled into a final package 700.

FIG. 7B is a bottom view of package 700 including chip 710 and corresponding traces 706 to electrically couple one or more pads of the chip 710 to the flexible substrate 702. The bottom view of package 700 shows one or more electronic components within chip 710 having pads, traces, and vias to electrically connect the chip 710 to external devices such as flexible circuit 500 and/or 602.

FIG. 7C is a view of an example flexible circuit in accordance with some embodiments. FIG. 7C is a view of a portion of a flexible circuit including reinforcing members 718, 720, 722, and 724. The reinforcing members shown are described herein with respect to at least FIGS. 3C and 3D. The reinforcing members may be of various materials and differ between reinforcing member 718, 720, 722, and 724.

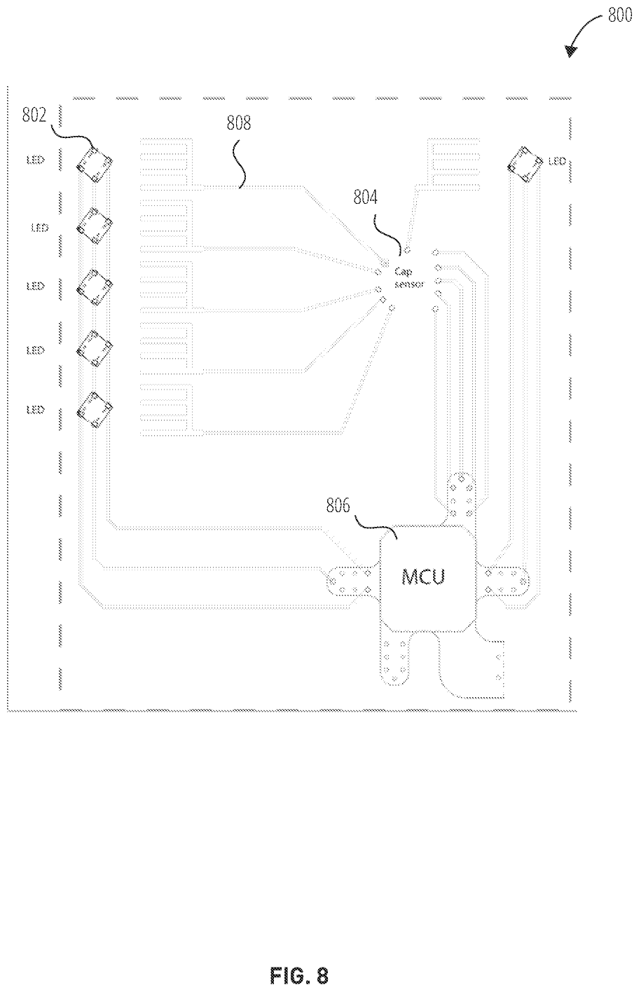

FIG. 8 is a view of an example flexible circuit board 800 in accordance with some embodiments. As described herein, island structures (e.g., 502, 504, 200, 300, 400) comprise a flexible substrate for an electronic component. In some embodiments, such electronic components of the respective island structures is a light emitting diode (LED) 802, a microcontroller unit (MCU) 806, a sensor 804, among others. Each of the described electronic components are of a rigid nature and electrically coupled by way of one or more traces 808.

In all examples, a structure may be constructed additively in a layer-by-layer process, where each layer is formed and placed on top (or below) previously assembled layers. Thus, each layer may be customized in many different ways so as to provide desired characteristics of the overall structure. Each layer may be formed from substantially one material, with the exception of a stencil layer, which as described above, has slots or channels filled with conductive gel. However, it should be noted that for low power circuits, the volume of metal required to perform the functions contemplated for the structures disclosed herein is relatively minimal. Thus, the resulting thicknesses of a metal layer may be very small, e.g., 200 microns or less, or approximately 0.010″ inches or less. Handling and assembling a layer this thin may be difficult in a manufacturing environment. Thus, e.g., the metal layer(s) 102 and, e.g., substrate layer(s) 104 may be provided as one film or layer when assembling, e.g., the structures 100. Furthermore, the single layer may be processed prior to assembly to a structure, for example, to remove un-needed metal material, for example by chemical etching as described above. Alternatively, the metal layer may be deposited additively to a laminate structure as a discrete layer. It may be advantageous to additively provide the metal layer when the structure requires the metal layer to have a relatively large surface area to perform the contemplated function, e.g.: to provide RF shielding to a circuit; act as a high-power bus; to serve as a ground plane; or other functions or configurations that may require a relatively large pattern or sheet of metal layer, or that may be easily provided as a discrete layer during a manufacturing operation. Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of components, modules, or mechanisms. Modules may constitute either software modules (e.g., code embodied on a machine-readable medium or in a transmission signal) or hardware modules. A “hardware module” is a tangible unit capable of performing certain operations and may be configured or arranged in a certain physical manner. In various example embodiments, one or more computer systems (e.g., a standalone computer system, a client computer system, or a server computer system) or one or more hardware modules of a computer system (e.g., a processor or a group of processors) may be configured by software (e.g., an application or application portion) as a hardware module that operates to perform certain operations as described herein.

In some embodiments, a hardware module may be implemented mechanically, electronically, or any suitable combination thereof. For example, a hardware module may include dedicated circuitry or logic that is permanently configured to perform certain operations. For example, a hardware module may be a special-purpose processor, such as a field programmable gate array (FPGA) or an ASIC. A hardware module may also include programmable logic or circuitry that is temporarily configured by software to perform certain operations. For example, a hardware module may include software encompassed within a general-purpose processor or other programmable processor. It will be appreciated that the decision to implement a hardware module mechanically, in dedicated and permanently configured circuitry, or in temporarily configured circuitry (e.g., configured by software) may be driven by cost and time considerations.

Accordingly, the phrase “hardware module” should be understood to encompass a tangible entity, be that an entity that is physically constructed, permanently configured (e.g., hardwired), or temporarily configured (e.g., programmed) to operate in a certain manner or to perform certain operations described herein. As used herein, “hardware-implemented module” refers to a hardware module. Considering embodiments in which hardware modules are temporarily configured (e.g., programmed), each of the hardware modules need not be configured or instantiated at any one instance in time. For example, where a hardware module comprises a general-purpose processor configured by software to become a special-purpose processor, the general-purpose processor may be configured as respectively different special-purpose processors (e.g., comprising different hardware modules) at different times. Software may accordingly configure a processor, for example, to constitute a particular hardware module at one instance of time and to constitute a different hardware module at a different instance of time.

Hardware modules can provide information to, and receive information from, other hardware modules. Accordingly, the described hardware modules may be regarded as being communicatively coupled. Where multiple hardware modules exist contemporaneously, communications may be achieved through signal transmission (e.g., over appropriate circuits and buses) between or among two or more of the hardware modules. In embodiments in which multiple hardware modules are configured or instantiated at different times, communications between such hardware modules may be achieved, for example, through the storage and retrieval of information in memory structures to which the multiple hardware modules have access. For example, one hardware module may perform an operation and store the output of that operation in a memory device to which it is communicatively coupled. A further hardware module may then, at a later time, access the memory device to retrieve and process the stored output. Hardware modules may also initiate communications with input or output devices, and can operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions described herein. As used herein, “processor-implemented module” refers to a hardware module implemented using one or more processors.

Similarly, the methods described herein may be at least partially processor-implemented, a processor being an example of hardware. For example, at least some of the operations of a method may be performed by one or more processors or processor-implemented modules. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an application program interface (API)).

The performance of certain of the operations may be distributed among the one or more processors, not only residing within a single machine, but deployed across a number of machines. In some example embodiments, the one or more processors or processor-implemented modules may be located in a single geographic location (e.g., within a home environment, an office environment, or a server farm). In other example embodiments, the one or more processors or processor-implemented modules may be distributed across a number of geographic locations.

The electrically conductive compositions, such as conductive gels, comprised in the articles described herein can, for example, have a paste like or gel consistency that can be created by taking advantage of, among other things, the structure that gallium oxide can impart on the compositions when gallium oxide is mixed into a eutectic gallium alloy. When mixed into a eutectic gallium alloy, gallium oxide can form micro or nanostructures that are further described herein, which structures are capable of altering the bulk material properties of the eutectic gallium alloy.

As used herein, the term “eutectic” generally refers to a mixture of two or more phases of a composition that has the lowest melting point, and where the phases simultaneously crystallize from molten solution at this temperature. The ratio of phases to obtain a eutectic is identified by the eutectic point on a phase diagram. One of the features of eutectic alloys is their sharp melting point.

The electrically conductive compositions can be characterized as conducting shear thinning gel compositions. The electrically conductive compositions described herein can also be characterized as compositions having the properties of a Bingham plastic. For example, the electrically conductive compositions can be viscoplastics, such that they are rigid and capable of forming and maintaining three-dimensional features characterized by height and width at low stresses but flow as viscous fluids at high stress. Thus, for example, the electrically conductive compositions can have a viscosity ranging from about 10,000,000 Pa*s to about 40,000,000 Pa*s under low shear and about 150 to 180 at high shear. For example under condition of low shear the composition has a viscosity of about 10,000,000 Pa*s, about 15,000,000 Pa*s, about 20,000,000 Pa*s, about 25,000,000 Pa*s, about 30,000,000 Pa*s, about 45,000,000 Pa*s, or about 40,000,000 Pa*s under conditions of low shear. Under condition of high shear the composition has a viscosity of about 150 Pa*s, about 155 Pa*s, about 160 Pa*s, 165 Pa*s, about 170 Pa*s, about 175 Pa*s, or about 180 Pa*s.

The electrically conductive compositions described herein can have any suitable conductivity, such as a conductivity of from about 2×10⁵ S/m to about 8×10⁵ S/m.

The electrically conductive compositions described herein can have any suitable melting point, such as a melting point of from about −20° C. to about 10° C., about −10° C. to about 5° C., about −5°° C. to about 5° C. or about −5° C. to about 0° C.

The electrically conductive compositions can comprise a mixture of a eutectic gallium alloy and gallium oxide, wherein the mixture of eutectic gallium alloy and gallium oxide has a weight percentage (wt %) of between about 59.9% and about 99.9% eutectic gallium alloy, such as between about 67% and about 90%, and a wt % of between about 0.1% and about 2.0% gallium oxide such as between about 0.2 and about 1%. For example, the electrically conductive compositions can have about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, about 95%, about 96%, about 97%, about 98%, about 99%, or greater, such as about 99.9% eutectic gallium alloy, and about 0.1%, about 0.2%, about 0.3%, about 0.4%, about 0.5%, about 0.6%, about 0.7%, about 0.8%, about 0.9%, about 1.0%, about 1.1%, about 1.2%, about 1.3%, about 1.4%, about 1.5%, about 1.6%, about 1.7%, about 1.8%, about 1.9%, and about 2.0% gallium oxide.

The eutectic gallium alloy can include gallium-indium or gallium-indium-tin in any ratio of elements. For example, a eutectic gallium alloy includes gallium and indium. The electrically conductive compositions can have any suitable percentage of gallium by weight in the gallium-indium alloy that is between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

The electrically conductive compositions can have a percentage of indium by weight in the gallium-indium alloy that is between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

The eutectic gallium alloy can include gallium and tin. For example, the electrically conductive compositions can have a percentage of tin by weight in the alloy that is between about 0.001% and about 50%, such as about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, or about 50%.

The electrically conductive compositions can comprise one or more micro-particles or sub-micron scale particles blended with the eutectic gallium alloy and gallium oxide. The particles can be suspended, either coated in eutectic gallium alloy or gallium and encapsulated in gallium oxide or not coated in the previous manner, within eutectic gallium alloy. The micro-or sub-micron scale particles can range in size from nanometer to micrometer and can be suspended in gallium, gallium-indium alloy, or gallium-indium-tin alloy. Particle to alloy ratio can vary and can change the flow properties of the electrically conductive compositions. The micro and nanostructures can be blended within the electrically conductive compositions through sonication or other suitable means. The electrically conductive compositions can include a colloidal suspension of micro and nanostructures within the eutectic gallium alloy/gallium oxide mixture.

The electrically conductive compositions can further include one or more micro-particles or sub-micron scale particles dispersed within the compositions. This can be achieved in any suitable way, including by suspending particles, either coated in eutectic gallium alloy or gallium and encapsulated in gallium oxide or not coated in the previous manner, within the electrically conductive compositions or, specifically, within the eutectic gallium alloy fluid. These particles can range in size from nanometer to micrometer and can be suspended in gallium, gallium-indium alloy, or gallium-indium-tin alloy. Particle to alloy ratio can vary, in order to, among other things, change fluid properties of at least one of the alloys and the electrically conductive compositions. In addition, the addition of any ancillary material to colloidal suspension or eutectic gallium alloy in order to, among other things, enhance or modify its physical, electrical or thermal properties. The distribution of micro and nanostructures within the at least one of the eutectic gallium alloy and the electrically conductive compositions can be achieved through any suitable means, including sonication or other mechanical means without the addition of particles. In certain embodiments, the one or more micro-particles or sub-micron particles are blended with the at least one of the eutectic gallium alloy and the electrically conductive compositions with wt % of between about 0.001% and about 40.0% of micro-particles, for example about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, or about 40.

The one or more micro-or sub-micron particles can be made of any suitable material including soda glass, silica, borosilicate glass, quartz, oxidized copper, silver coated copper, non-oxidized copper, tungsten, super saturated tin granules, glass, graphite, silver coated copper, such as silver coated copper spheres, and silver coated copper flakes, copper flakes, or copper spheres, or a combination thereof, or any other material that can be wetted by the at least one of the eutectic gallium alloy and the electrically conductive compositions. The one or more micro-particles or sub-micron scale particles can have any suitable shape, including the shape of spheroids, rods, tubes, a flakes, plates, cubes, prismatic, pyramidal, cages, and dendrimers. The one or more micro-particles or sub-micron scale particles can have any suitable size, including a size range of about 0.5 microns to about 60 microns, as about 0.5 microns, about 0.6 microns, about 0.7 microns, about 0.8 microns, about 0.9 microns, about 1 microns, about 1.5 microns, about 2 microns, about 3 microns, about 4 microns, about 5 microns, about 6 microns, about 7 microns, about 8 microns, about 9 microns, about 10 microns, about 11 microns, about 12 microns, about 13 microns, about 14 microns, about 15 microns, about 16 microns, about 17 microns, about 18 microns, about 19 microns, about 20 microns, about 21 microns, about 22 microns, about 23 microns, about 24 microns, about 25 microns, about 26 microns, about 27 microns, about 28 microns, about 29 microns, about 30 microns, about 31 microns, about 32 microns, about 33 microns, about 34 microns, about 35 microns, about 36 microns, about 37 microns, about 38 microns, about 39 microns, about 40 microns, about 41 microns, about 42 microns, about 43 microns, about 44 microns, about 45 microns, about 46 microns, about 47 microns, about 48 microns, about 49 microns, about 50 microns, about 51 microns, about 52 microns, about 53 microns, about 54 microns, about 55 microns, about 56 microns, about 57 microns, about 58 microns, about 59 microns, or about 60 microns.

The electrically conductive compositions described herein can be made by any suitable method, including a method comprising blending surface oxides formed on a surface of a eutectic gallium alloy into the bulk of the eutectic gallium alloy by shear mixing of the surface oxide/alloy interface. Shear mixing of such compositions can induce a cross linked microstructure in the surface oxides; thereby forming a conducting shear thinning gel composition. A colloidal suspension of micro-structures can be formed within the eutectic gallium alloy/gallium oxide mixture, for example as, gallium oxide particles and/or sheets.

The surface oxides can be blended in any suitable ratio, such as at a ratio of between about 59.9% (by weight) and about 99.9% eutectic gallium alloy, to about 0.1% (by weight) and about 2.0% gallium oxide. For example percentage by weight of gallium alloy blended with gallium oxide is about 60%, 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, about 95%, about 96%, about 97%, about 98%, about 99%, or greater, such as about 99.9% eutectic gallium alloy while the weight percentage of gallium oxide is about 0.1%, about 0.2%, about 0.3%, about 0.4%, about 0.5%, about 0.6%, about 0.7%, about 0.8%, about 0.9%, about 1.0%, about 1.1%, about 1.2%, about 1.3%, about 1.4%, about 1.5%, about 1.6%, about 1.7%, about 1.8%, about 1.9%, and about 2.0% gallium oxide. In embodiments, the eutectic gallium alloy can include gallium-indium or gallium-indium-tin in any ratio of the recited elements. For example, a eutectic gallium alloy can include gallium and indium.

The weight percentage of gallium in the gallium-indium alloy can be between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

Alternatively or in addition, the weight percentage of indium in the gallium-indium alloy can be between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

A eutectic gallium alloy can include gallium, indium, and tin. The weight percentage of tin in the gallium-indium-tin alloy can be between about 0.001% and about 50%, such as about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, or about 50%.

The weight percentage of gallium in the gallium-indium-tin alloy can be between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

Alternatively or in addition, the weight percentage of indium in the gallium-indium-tin alloy can be between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

One or more micro-particles or sub-micron scale particles can be blended with the eutectic gallium alloy and gallium oxide. For example, the one or more micro-particles or sub-micron particles can be blended with the mixture with wt % of between about 0.001% and about 40.0% of micro-particles in the composition, for example about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, or about 40. In embodiments the particles can be soda glass, silica, borosilicate glass, quartz, oxidized copper, silver coated copper, non-oxidized copper, tungsten, super saturated tin granules, glass, graphite, silver coated copper, such as silver coated copper spheres, and silver coated copper flakes, copper flakes or copper spheres or a combination thereof, or any other material that can be wetted by gallium. In some embodiments the one or more micro-particles or sub-micron scale particles are in the shape of spheroids, rods, tubes, a flakes, plates, cubes, prismatic, pyramidal, cages, and dendrimers. In certain embodiments, the one or more micro-particles or sub-micron scale particles are in the size range of about 0.5 microns to about 60 microns, as about 0.5 microns, about 0.6 microns, about 0.7 microns, about 0.8 microns, about 0.9 microns, about 1 microns, about 1.5 microns, about 2 microns, about 3 microns, about 4 microns, about 5 microns, about 6 microns, about 7 microns, about 8 microns, about 9 microns, about 10 microns, about 11 microns, about 12 microns, about 13 microns, about 14 microns, about 15 microns, about 16 microns, about 17 microns, about 18 microns, about 19 microns, about 20 microns, about 21 microns, about 22 microns, about 23 microns, about 24 microns, about 25 microns, about 26 microns, about 27 microns, about 28 microns, about 29 microns, about 30 microns, about 31 microns, about 32 microns, about 33 microns, about 34 microns, about 35 microns, about 36 microns, about 37 microns, about 38 microns, about 39 microns, about 40 microns, about 41 microns, about 42 microns, about 43 microns, about 44 microns, about 45 microns, about 46 microns, about 47 microns, about 48 microns, about 49 microns, about 50 microns, about 51 microns, about 52 microns, about 53 microns, about 54 microns, about 55 microns, about 56 microns, about 57 microns, about 58 microns, about 59 microns, or about 60 microns.

### EXAMPLES

Example 1 is an apparatus, comprising: a metal layer including a metal pattern; a fluid phase conductor configured to overlap at least a first portion of the metal pattern of the metal layer; and a first encapsulation layer disposed on the metal layer, the first encapsulation layer having one or more vias filled with the fluid phase conductor and configured to encapsulate the fluid phase conductor within the apparatus.

In Example 2, the subject matter of Example 1 includes, a second encapsulation layer.

In Example 3, the subject matter of any one or more of Examples 1 and 2 includes, a stencil layer configured to provide electrical communication to the first encapsulation layer by way of at least one of a plurality of vias in the first encapsulation layer.

In Example 4, the subject matter of any one or more of Examples 1-3 includes, a second stencil layer including a second pattern of slots containing the fluid phase conductor.

In Example 5, the subject matter of any one or more of Examples 1-4 includes, wherein the second stencil layer is adhered to the second encapsulation layer.

In Example 6, the subject matter of any one or more of Examples 1-5 includes, wherein the second encapsulation layer is adhered to the first stencil layer.

In Example 7, the subject matter of any one or more of Examples 1-6 includes, an electronic component coupled to the metal layer.

In Example 8, the subject matter of any one or more of Examples 1-7 includes, a discrete reinforcement segment configured to support the electronic component.

In Example 9, the subject matter of any one or more of Examples 1-8 includes, wherein the discrete reinforcement segment is inserted between two layers.

In Example 10, the subject matter of any one or more of Examples 1-9 includes, wherein the discrete reinforcement segment causes the apparatus to have a bend radius larger than twice a length of the electronic component.

In Example 11, the subject matter of any one or more of Examples 1-10 includes, wherein the discrete reinforcement segment is a textile segment.

In Example 12, the subject matter of any one or more of Examples 1-11 includes, wherein the discrete reinforcement segment is a polymer film segment.

In Example 13, the subject matter of any one or more of Examples 1-12 includes, wherein the polymer film is a polyimide film.

Example 14 is an apparatus, comprising: a metal layer; a substrate layer coupled to the metal layer; a fluid phase conductor wetted to the metal layer and the substrate layer; and an encapsulation layer encapsulating the metal layer and the fluid phase conductor.

In Example 15, the subject matter of Example 14 includes, a stencil layer containing a fluid phase conductor, wherein the encapsulation layer is coupled to the stencil layer.

In Example 16, the subject matter of any one or more of Examples 14 and 15 includes, wherein the metal layer is a first metal layer, the substrate layer is a first substrate layer, the metal layer and the substrate layer form a first segment, and further comprising: a second segment including a second substrate layer; a third segment including a third substrate layer, wherein the fluid phase conductor is wetted to the metal layer and the third substrate layer; and a third encapsulation layer encapsulating the metal layer and the third substrate layer, wherein the second segment is electrically coupled to at least a portion of the third segment.

In Example 17, the subject matter of any one or more of Examples 14-16 includes, an electronic component electrically coupled to the second metal layer.

In Example 18, the subject matter of any one or more of Examples 14-17 includes, wherein the metal layer is a first metal layer, the substrate layer is a first substrate layer, the metal layer and the substrate layer form a first segment, and further comprising: a second segment including a second substrate layer; a third segment including the fluid phase conductor having a predetermined current conductivity.

In Example 19, the subject matter of any one or more of Examples 14-18 includes, an electronic component electrically coupled to the second metal layer.

In Example 20, the subject matter of any one or more of Examples 14-19 includes, wherein the electronic component is selected from the group consisting of: a terminal to an external device, a integrated circuit, a chip, a resistor, a capacitor, or an inductor.

In Example 21, the subject matter of any one or more of Examples 14-20 includes, wherein the electronic component is an integrated circuit (IC).

In Example 22, the subject matter of any one or more of Examples 14-21 includes, wherein the electronic component is a first electronic component mechanically coupled to the second metal layer and further comprising a second electronic component mechanically coupled to the encapsulation layer, wherein the second electronic component has a physical size factor that is larger than the first electronic component.

In Example 23, the subject matter of any one or more of Examples 14-22 includes, wherein the physical size factor corresponds to an SMT package standard.

In Example 24, the subject matter of any one or more of Examples 14-23 includes, SMT package size.

In Example 25, the subject matter of any one or more of Examples 14-24 includes, Amperes.

In Example 26, the subject matter of any one or more of Examples 14-25 includes, Amperes.

In Example 27, the subject matter of any one or more of Examples 14-26 includes, wherein the metal layer has a maximum current greater than a maximum current of the fluid phase conductor.

Example 28 is an apparatus, comprising: a metal layer to provide an electrical connection; a stencil layer forming a first pattern of apertures within the stencil layer, the apertures containing a fluid phase conductor; and a first encapsulation layer disposed between the metal layer and the stencil layer; and a second encapsulation layer; wherein the first and second encapsulation layers are configured to encapsulate the fluid phase conductor within the apparatus.

In Example 29, the subject matter of Example 28 includes, wherein the metal layer is configured as a ground plane.

In Example 30, the subject matter of any one or more of Examples 28 and 29 includes, wherein the apertures within the stencil layer are slots.

In Example 31, the subject matter of any one or more of Examples 28-30 includes, wherein the stencil layer is a first stencil layer, the apparatus further comprising a second stencil layer forming a second pattern of apertures, the apertures containing the fluid phase conductor.

In Example 32, the subject matter of any one or more of Examples 28-31 includes, an isolation layer disposed between the first stencil layer and the second stencil layer, the isolation layer including one or more vias configured to provide electrical contact between at least one slot of the first pattern of slots of the first stencil layer and at least one slot of the second pattern of slots of the second stencil layer.

Example 33 is an apparatus, comprising: a metal layer including a metal pattern, the metal pattern having a first trace width; a stencil layer forming a first pattern of apertures within the stencil layer, the apertures containing a fluid phase conductor and configured to overlap at least a first portion of the metal pattern of the metal layer; and a first encapsulation layer disposed between the metal layer and the stencil layer, the first encapsulation layer having one or more vias filled with the fluid phase conductor and configured to encapsulate the fluid phase conductor within the apparatus.

In Example 34, the subject matter of Example 33 includes, wherein the apertures within the stencil layer are slots.

In Example 35, the subject matter of any one or more of Examples 33 and 34 includes, wherein the first pattern of apertures containing the fluid phase conductor has a second trace width greater than the first trace width of the metal pattern.

In Example 36, the subject matter of any one or more of Examples 33-35 includes that the second trace width has a first minimum value that is not less than fifty (50) micrometers and not more than five hundred (500) micrometers and the first trace width has a second minimum value that is less than the first minimum value.

In Example 37, the subject matter of any one or more of Examples 33-36 includes, wherein an aperture spacing between at least two adjacent apertures of the first pattern of apertures is greater than a trace spacing between at least two adjacent traces of the metal pattern.

In Example 38, the subject matter of any one or more of Examples 33-37 includes, an electronic component electrically coupled to the metal layer.

In Example 39, the subject matter of any one or more of Examples 33-38 includes, wherein the electronic component is a first electronic component, the apparatus further comprising a second electronic component electrically coupled to the stencil layer.

In Example 40, the subject matter of any one or more of Examples 33-39 includes, wherein the second electronic component is electrically coupled to the stencil layer by way of the one or more apertures of the stencil layer and one or more of the vias in the first encapsulation layer.

In Example 41, the subject matter of any one or more of Examples 33-40 includes, a second encapsulation layer adhered to the stencil layer on a surface opposite the first encapsulation layer.

In Example 42, the subject matter of any one or more of Examples 33-41 includes, wherein the electric component is physically coupled to the metal layer.

In Example 43, the subject matter of any one or more of Examples 33-42 includes, wherein the electric component is physically coupled to the second encapsulation layer.

In Example 44, the subject matter of any one or more of Examples 33-43 includes, wherein the second encapsulation layer comprises at least one via containing a fluid phase conductor and the electric component is electrically coupled to the metal layer by one or more slots of the stencil layer, at least one via in the first encapsulation layer, and at least one via in the second encapsulation layer.

Example 45 is at least one machine-readable medium including instructions that, when executed by processing circuitry, cause the processing circuitry to perform operations to implement of any of Examples 1-44.

Example 46 is an apparatus comprising means to implement of any of Examples 1-44.

Example 47 is a system to implement of any of Examples 1-44.

Example 48 is a method to make or implement of any of Examples 1-44.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or any suitable combination thereof), registers, or other machine components that receive, store, transmit, or display information. Furthermore, unless specifically stated otherwise, the terms “a” or “an” are herein used, as is common in patent documents, to include one or more than one instance. Finally, as used herein, the conjunction “or” refers to a non-exclusive “or,” unless specifically stated otherwise.

What is claimed is:

1. An apparatus, comprising:
a metal layer including a metal pattern;
a fluid phase conductor configured to overlap at least a first portion of the metal pattern of the metal layer; and
a first encapsulation layer disposed on the metal layer, the first encapsulation layer having one or more vias filled with the fluid phase conductor and configured to encapsulate the fluid phase conductor within the apparatus.

2. The apparatus of claim 1, further comprising a second encapsulation layer.

3. The apparatus of claim 2, further comprising a stencil layer configured to provide electrical communication to the first encapsulation layer by way of at least one of a plurality of vias in the first encapsulation layer.

4. The apparatus of claim 3, further comprising a second stencil layer including a second pattern of slots containing the fluid phase conductor.

5. The apparatus of claim 4, wherein the second stencil layer is adhered to the second encapsulation layer.

6. The apparatus of claim 3, wherein the second encapsulation layer is adhered to the first stencil layer.

7. The apparatus of claim 3, further comprising an electronic component coupled to the metal layer.

8. The apparatus of claim 7, further comprises a discrete reinforcement segment configured to support the electronic component.

9. The apparatus of claim 8, wherein the discrete reinforcement segment is inserted between two layers.

10. The apparatus of claim 8, wherein the discrete reinforcement segment causes the apparatus to have a bend radius larger than twice a length of the electronic component.

11. The apparatus of claim 8, wherein the discrete reinforcement segment is a textile segment.

12. The apparatus of claim 11, wherein the discrete reinforcement segment is a polymer film segment.

13. The apparatus of claim 12, wherein the polymer film is a polyimide film.

14. An apparatus, comprising:
a metal layer;
a substrate layer coupled to the metal layer;
a fluid phase conductor wetted to the metal layer and the substrate layer; and
an encapsulation layer encapsulating the metal layer and the fluid phase conductor.

15. The apparatus of claim 14, further comprising:
a stencil layer containing a fluid phase conductor, wherein the encapsulation layer is coupled to the stencil layer.

16. The apparatus of claim 14, wherein the metal layer is a first metal layer, the substrate layer is a first substrate layer, the metal layer and the substrate layer form a first segment, and further comprising:
a second segment including a second substrate layer;
a third segment including a third substrate layer, wherein the fluid phase conductor is wetted to the metal layer and the third substrate layer; and
a third encapsulation layer encapsulating the metal layer and the third substrate layer,
wherein the second segment is electrically coupled to at least a portion of the third segment.

17. The apparatus of claim 16, further comprising an electronic component electrically coupled to the second metal layer.

18. The apparatus of claim 14, wherein the metal layer is a first metal layer, the substrate layer is a first substrate layer, the metal layer and the substrate layer form a first segment, and further comprising:
a second segment including a second substrate layer;
a third segment including the fluid phase conductor having a predetermined current conductivity.

19. The apparatus of claim 18, further comprising an electronic component electrically coupled to the second metal layer.

20. The apparatus of claim 19, wherein the electronic component is selected from the group consisting of: a terminal to an external device, a integrated circuit, a chip, a resistor, a capacitor, or an inductor.

21. The apparatus of claim 19, wherein the electronic component is an integrated circuit (IC).

22. The apparatus of claim 17, wherein the electronic component is a first electronic component mechanically coupled to the second metal layer and further comprising a second electronic component mechanically coupled to the encapsulation layer, wherein the second electronic component has a physical size factor that is larger than the first electronic component.

23. The apparatus of claim 22, wherein the physical size factor corresponds to an SMT package standard.

24. The apparatus of claim 22, wherein the physical size factor is at least an 0603 SMT package size.

25. The apparatus of claim 16, wherein the fluid phase conductor has a maximum current of not more than 1.5 Amperes.

26. The apparatus of claim 25, wherein the maximum current of the fluid phase conductor is not more than 1.0 Amperes.

27. The apparatus of claim 16, wherein the metal layer has a maximum current greater than a maximum current of the fluid phase conductor.
